(19) United States
(12) Patent Application Publication
(10) Pub. No.: US 2026/0189195 A1
(43) Pub. Date: Jul. 2, 2026

(54) FEED-FORWARD AMPLIFIER AND METHOD FOR TRANSITIONING BETWEEN OFFLINE AND ONLINE TUNING STATES

(71) Applicant: MOTOROLA SOLUTIONS, INC., Chicago, IL (US)

(72) Inventors: Niels-Henrik Lai HANSEN, Frederiksberg (DK); Gregory J. BUCHWALD, Crystal Lake, IL (US); Rodney W. HAGEN, Lake in the Hills, IL (US); Mitchell R. BLOZINSKI, Lake in the Hills, IL (US)

(21) Appl. No.: 19/003,017

(22) Filed: Dec. 27, 2024

(51) Int. Cl. H03F 1/32; H03F 3/24

(52) U.S. Cl. CPC H03F 1/3235; H03F 3/24; H03F 2201/3212; H03F 2201/3218

(57) ABSTRACT

Tuning of carrier and intermodulation cancellation loops of a feed-forward amplifier at a radio transmitter occurs. For the CC loop, in an absence of carriers, a preheating process comprises enabling: a main power amplifier of the CC loop and tone(s) operatively coupled to an input of the feed-forward amplifier; tuning the CC loop using the tone(s) occurs to determine tone CC loop tuning parameters, which, when a carrier is about to be keyed at the radio transmitter are used to determine carrier CC loop offsets that are applied to the CC loop. For IMDC loop tuning, the preheating process is modified to enable an error power amplifier of the IMDC loop and tone(s) within the main power amplifier path to determine tone IMDC loop tuning parameters which, when a carrier is about to be keyed are used to determine carrier IMDC loop offsets that are applied to the IMDC loop.

### BACKGROUND OF THE INVENTION

Feed-Forward Power Amplifiers (PA) require accurate internal tuning in order to operate properly. The internal tuning can relate to linearity correction or power efficiency, for example. In present feed-forward PAs, this tuning requires the presence of input carriers to the PA. Conventional Land Mobile Radio (LMR) applications have very dynamic transmitter carrier conditions, which include long periods of time where there are no carrier(s) present. Since there can be long periods of time with no carrier(s) present, feed-forward PAs cannot support conventional LMR, as the required tuning may not be maintained during periods where no carrier(s) are present.

### BRIEF DESCRIPTION OF THE SEVERAL VIEWS OF THE DRAWINGS

In the accompanying figures similar or the same reference numerals may be repeated to indicate corresponding or analogous elements. These figures, together with the detailed description, below are incorporated in and form part of the specification and serve to further illustrate various embodiments of concepts that include the claimed invention, and to explain various principles and advantages of those embodiments.

FIG. 1 is a feed-forward amplifier for transitioning from offline to online tuning states, in accordance with some examples; specifically, FIG. 1 shows the feed-forward amplifier in on online tuning state.

FIG. 2 depicts the feed-forward amplifier of FIG. 1 in an offline tuning state for tuning a carrier cancellation loop of the feed-forward amplifier, that may comprise a startup offline tuning state.

FIG. 3 depicts the feed-forward amplifier of FIG. 1 in an offline tuning state for tuning an intermodulation cancellation loop of the feed-forward amplifier, that may comprise a startup offline tuning state.

FIG. 4 depicts the feed-forward amplifier of FIG. 1 in another optional offline tuning state, that may comprise an offline tuning state used after the feed-forward amplifier has been in the online tuning state at least once.

FIG. 5 is a flowchart of a process for transitioning from offline to online tuning states in the feed-forward amplifier of FIG. 1, in accordance with some examples.

Skilled artisans will appreciate that elements in the figures are illustrated for simplicity and clarity and have not necessarily been drawn to scale. For example, the dimensions of some of the elements in the figures may be exaggerated relative to other elements to help improve understanding of embodiments of the present disclosure.

The system, apparatus, and process components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

### DETAILED DESCRIPTION OF THE INVENTION

Radio-Frequency (RF) power amplifiers generally undergo rapid thermally induced changes in gain and phase response upon key-up. Feed-Forward (FF) loops are very sensitive to these changes, and these changes may occur much faster than may be realistically compensated by certain tuning algorithms. Furthermore, dynamic carrier conditions may necessitate between switching between offline and online tuning states, and transitions from offline to online tuning states are prone to instantaneous de-tuning of the FF loops that may result in spectral distortion. For example, there may be long periods of time (e.g., 10 or more seconds) of carriers being transmitted are degraded with respect to spectral distortion (e.g., after transitioning from an offline to online tuning), which may lead to carrier transmission being spuriously high. therefore a need exists for feed-forward amplifier and method for transitioning the feed-forward amplifier between offline and online tuning states.

An aspect of the present specification provides a method implemented at a radio transmitter comprising a feed-forward amplifier comprising a carrier cancellation (CC) loop and an intermodulation cancellation (IMDC) loop, the method comprising: in an absence of carriers, implementing a preheating process comprising: enabling a main power amplifier of the CC loop; enabling one or more tones at a predetermined frequency and a predetermined power operatively coupled to an input of the feed-forward amplifier; and tuning the CC loop using the one or more tones and determining tone CC loop tuning parameters; and when a carrier is about to be keyed at the radio transmitter: determining carrier CC loop offset parameters from the tone CC loop tuning parameters; and applying the carrier CC loop offset parameters to the CC loop.

Another aspect of the present specification provides a radio transmitter comprising: a feed-forward amplifier comprising a carrier cancellation (CC) loop and an intermodulation cancellation (IMDC) loop; a processor; and a computer-readable storage medium having stored thereon program instructions that, when executed by the processor, causes the processor to perform a set of operations comprising: in an absence of carriers, implementing a preheating process comprising: enabling a main power amplifier of the CC loop; enabling one or more tones at a predetermined frequency and a predetermined power operatively coupled to an input of the feed-forward amplifier; and tuning the CC loop using the one or more tones and determining tone CC loop tuning parameters; and when a carrier is about to be keyed at the radio transmitter: determining carrier CC loop offset parameters from the tone CC loop tuning parameters; and applying the carrier CC loop offset parameters to the CC loop.

A further aspect of the present specification provides a method implemented at a radio transmitter comprising a feed-forward amplifier comprising a carrier cancellation (CC) loop and an intermodulation cancellation (IMDC) loop, the method comprising: in an absence of carriers, implementing a preheating process comprising: enabling an error power amplifier of the IMDC loop; enabling a one or more tones at a predetermined frequency and a predetermined power within the main power amplifier path; and tuning the IMDC loop using the one or more tones and determining tone IMDC loop tuning parameters; and when a carrier is about to be keyed at the radio transmitter: determining carrier IMDC loop offset parameters from the tone IMDC loop tuning parameters; and applying the carrier IMDC loop offset parameters to the IMDC loop.

Yet a further aspect of the present specification provides a radio transmitter comprising: a feed-forward amplifier comprising a carrier cancellation (CC) loop and an intermodulation cancellation (IMDC) loop; a processor; and a computer-readable storage medium having stored thereon program instructions that, when executed by the processor, causes the processor to perform a set of operations comprising: in an absence of carriers, implementing a preheating process comprising: enabling an error power amplifier of the IMDC loop; enabling a one or more tones at a predetermined frequency and a predetermined power within the main power amplifier path; and tuning the IMDC loop using the one or more tones and determining tone IMDC loop tuning parameters; and when a carrier is about to be keyed at the radio transmitter: determining carrier IMDC loop offset parameters from the tone IMDC loop tuning parameters; and applying the carrier IMDC loop offset parameters to the IMDC loop.

Each of the above-mentioned embodiments will be discussed in more detail below, starting with example system and device architectures of the system in which the embodiments may be practiced, followed by an illustration of processing blocks for a method for transitioning the feed-forward amplifier between offline and online tuning states

Example embodiments are herein described with reference to flowchart illustrations and/or block diagrams of methods, apparatus (systems) and computer program products according to example embodiments. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a special purpose and unique machine, such that the instructions, which execute via processor of the computer or other programmable data processing apparatus, create means for implementing the functions/acts specified in the flowchart and/or block diagram block or blocks. The methods and processes set forth herein need not, in some embodiments, be performed in the exact sequence as shown and likewise various blocks may be performed in parallel rather than in sequence. Accordingly, the elements of methods and processes are referred to herein as “blocks” rather than “steps.”

These computer program instructions may also be stored in a computer-readable memory that can direct a computer or other programmable data processing apparatus to function in a particular manner, such that the instructions stored in the computer-readable memory produce an article of manufacture including instructions, which implement the function/act specified in the flowchart and/or block diagram block or blocks.

Further advantages and features consistent with this disclosure will be set forth in the following detailed description, with reference to the drawings.

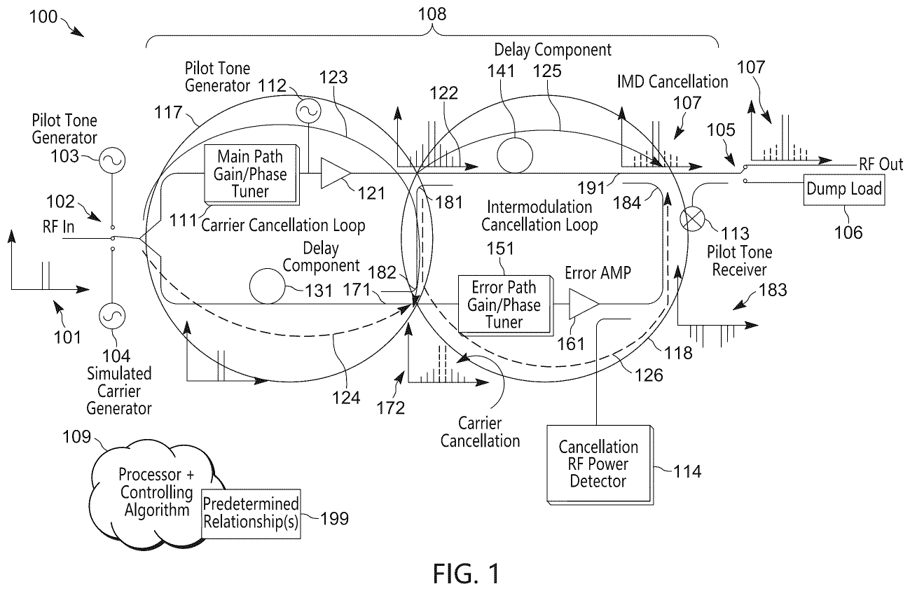

Attention is next directed to FIG. 1 which depicts a feed-forward (FF) amplifier 100. The FF amplifier 100 is understood to be a component of a radio transmitter, which may include, but is not limited to, an LMR radio and the like. For simplicity, references herein to a radio are understood to include a radio transmitter.

FIG. 1 shows operation of a carrier cancellation loop 117 and an intermodulation cancellation loop 118 of the feed-forward amplifier 100 in an online tuning state. In the depicted online tuning state, a one or more carrier input signals 101 (e.g., an RF input signal) are received, and a switch 102 to an input of the FF amplifier 100 is controlled to a position in which the carrier input signal 101 is received at an input to the FF amplifier 100. The position of the switch 102 may be referred to as an online tuning position. For simplicity, the one or more carrier input signals 101 are referred to as the carrier input signal 101; this convention is used throughout the present specification.

The carrier input signal 101 is depicted on a graph that is understood to indicate frequency on an x-axis, and amplitude on a y-axis. This convention will be used throughout the present specification. Hence, as depicted, the carrier input signal 101 includes two carrier frequencies (e.g., two carriers) of about the same amplitude, however, the carrier input signal 101 may have any suitable number of frequencies, at any suitable amplitudes, which may be the same or different from each other.

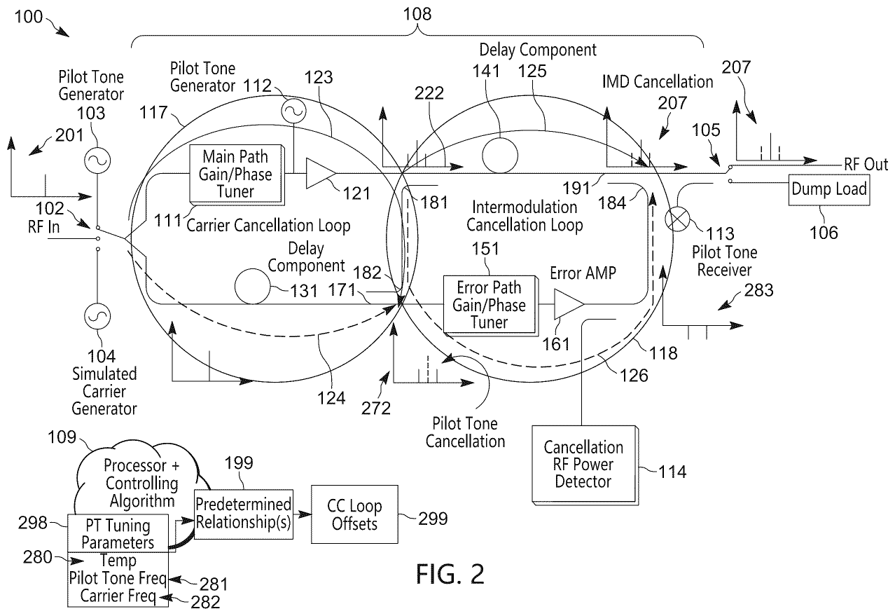

The switch 102 may be controlled to at least two positions, however. For example, with brief reference to FIG. 2, the switch 102 may be controlled to an offline tuning position (that is used at least upon startup), in which a pilot tone (e.g., or any suitable one or more tones) is received, at the input to the FF amplifier 100, from a pilot tone generator 103 in an offline tuning state and/or a startup offline tuning state.

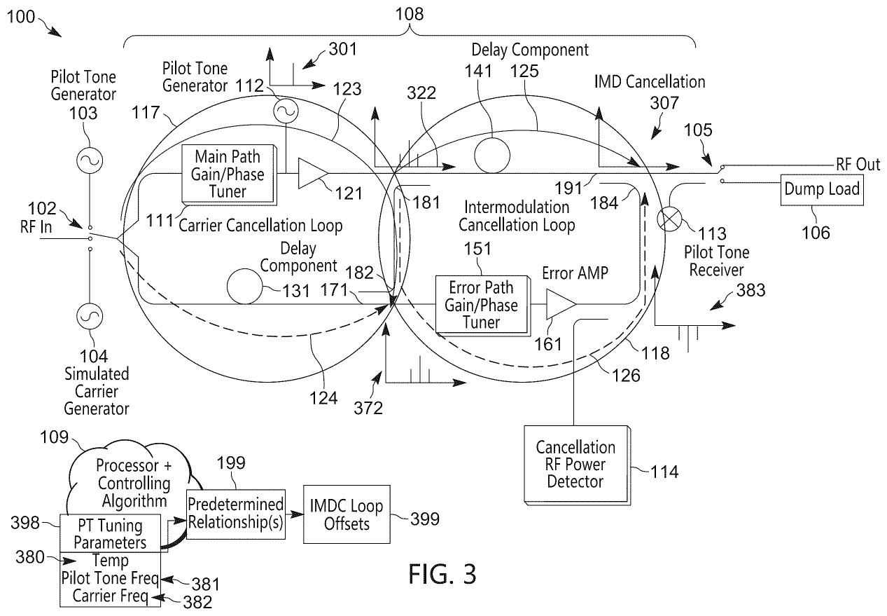

Similarly, with brief reference to FIG. 3, the switch 102 may optionally be controlled to any of the tuning positions including being disconnected from any of the tuning positions.

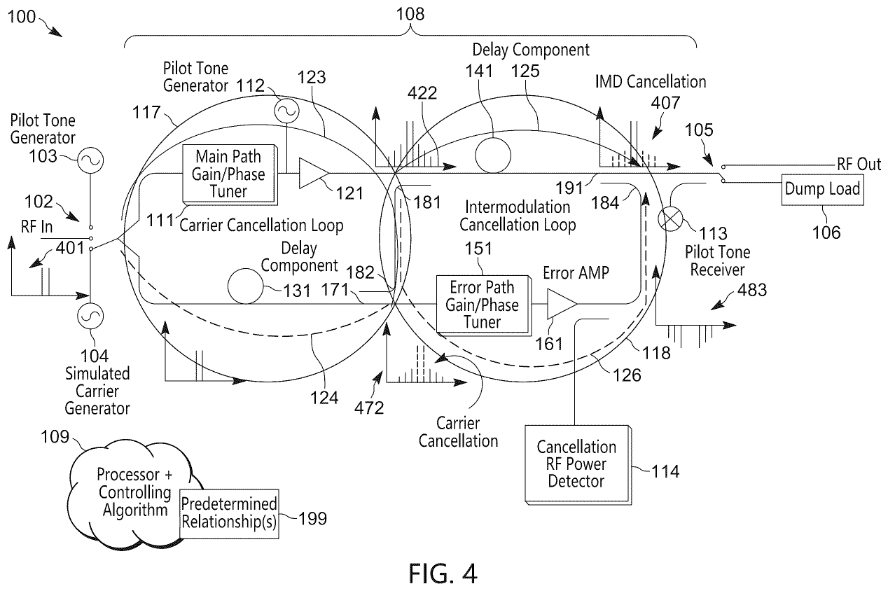

Similarly, with brief reference to FIG. 4, the switch 102 may optionally be controlled to a second offline tuning position (that may be used after transitioning from an online tuning state to an offline tuning state that is not the startup offline tuning state), in which a simulated carrier signal is received from a simulated carrier generator 104 in offline tuning state that is not the startup tuning state. The second offline tuning position may represent an optional third position to which the switch 102 may be controlled.

Also depicted in FIG. 1, FIG. 2, FIG. 3 and FIG. 4 is a switch 105 at an output to the FF amplifier 100, which, as depicted in FIG. 1, is a state in which a carrier output signal 107 (e.g., two or more carrier output signals 107) is output from the FF amplifier 100. In FIG. 2 and FIG. 3, the switch 105 is in the same position as in FIG. 1. However in FIG. 4 the switch 105 is controlled to a position that directs output from the FF amplifier 100 into a dump load 106, for example an RF absorbing material and/or circuit; in these examples, an output simulated carrier signal is directed to the dump load 106, and not transmitted, described in further detail with respect to FIG. 4.

However, in some examples, in the offline tuning states of FIG. 2 and FIG. 3, the switch 105 may be used to direct an output pilot tone (e.g., or any suitable one or more output tones) to the dump load 106.

It is further understood that the simulated carrier generator 104, the switch 105, the dump load 106, and the position of the switch 102 that connects the FF amplifier 100 to the simulated carrier generator 104 may be optional.

Returning to FIG. 1, the FF amplifier 100 comprises certain core components 108 including a main path gain/phase tuner 111 (e.g., a combination of a gain tuner and a phase tuner that respectively shift gain and phase of a signal input thereto), a main power amplifier 121, a carrier cancellation loop delay component 131, an intermodulation cancellation (IMDC) loop delay component 141, an error path gain/phase tuner 151 (e.g., a combination of a gain tuner and a phase tuner that respectively shift gain and phase of a signal input thereto), an error power amplifier 161, a pilot tone generator (PTG) 112, a pilot tone receiver (PTR) 113, a cancellation RF power detector 114, a main path carrier cancellation coupler 181, a clean path carrier cancellation coupler 182, an error cancellation IMDC coupler 184, an IMDC summing node 191, the carrier output signal 107, a carrier cancellation summing node 171, and a carrier cancellation error signal 172. The PTG 112 may be different from the PTG 103, or functionality of the PTGs 103, 112 may be combined, such that a single PTG 103 may be operatively connected to different positions of the FF amplifier 100 using any suitable number of switches (e.g., including, but not limited to, the PTG 112 being absent, and the PTG 103 being used to provide a pilot tone for IMDC loop tuning, on the main power amplifier path 123, as described herein with respect to FIG. 3, though in such an example, the PTG 103 does not provide a pilot tone on the delay path 124 (e.g., commonly and interchangeably referred to as the “clean path”).

One skilled in the art will appreciate that in place of a pilot tone, tuning of the loops 117, 118 as described herein could be performed in any other suitable manner, which may include, but is not limited to a pilot tone, multiple tones, a correlator signal, and the like, amongst other possibilities. In the example of a correlator signal it is understood that the FF amplifier 100 maybe a component of a radio transmitter that utilizes multiple signal component inputs arranged in a known time and frequency sequence thereby allowing a matched filter to align with the signal, cancel the correlation signal components by matching either gain (envelope) and phase or In-Phase (I) and Quadrature (Q) components of the main and feedforward cancellation path thereby allowing only the undesired distortion components to remain.

Hence, while the terms pilot tone, pilot tone generator and pilot tone receiver are used throughout the present specification, it is understood that any suitable one or more tones may be used to performing tuning of the FF amplifier 100 as described herein.

Components of the FF amplifier 100 are further understood to be communicatively coupled to a processor 109 (e.g., that may include, but is not limited to, one or more microprocessors, one or more CPUs (Central Processing Units), and the like, amongst other possibilities). For example, the FF amplifier 100 may be a component of a radio (e.g., not depicted, but which may include, but is not limited to, a land mobile radio (LMR), a digital mobile radio (DMR) and the like, used by first responders, amongst other possibilities), and the processor 109 may be a processor of such a radio. The processor 109 is represented as a cloud to indicate other components of such a radio, such a memory, a computer readable storage medium, and the like.

Furthermore, while not depicted, the processor 109 is understood to be communicatively coupled to components of the FF amplifier 100, such that the processor 109 may control those components into various states, as described herein, including, but not limited to, the various switches, amplifiers, gain/phase tuners, and the like, and may further receive output from the various detectors and/or receivers as described herein. Hence, when a component of the FF amplifier 100 is described as being adjusted and/or controlled herein, and reference is not made to the processor 109 performing such actions, it is nonetheless understood that the processor 109 performs such actions.

The FF amplifier 100 is further understood to include a carrier cancellation (CC) loop 117, which generally comprises two paths: a main power amplifier path 123 and a delay path 124 (e.g., the “clean path”).

The main power amplifier path 123 comprises the main path gain/phase tuner 111, the main power amplifier 121, a main path carrier cancellation coupler 181, and a clean path carrier cancellation coupler 182.

The delay path 124 (e.g., the “clean path”) comprises the delay component 131, where the delay component 131, provided in the CC loop 117, generally closely matches the group delay of the two paths 123, 124 of the CC loop 117 with minimal delay error in order to achieve optimal operational bandwidth.

The IMDC loop 118 comprises two respective paths: an error power amplifier path 126 and an IMDC loop delay path 125.

The error power amplifier path 126 comprises the error path gain/phase tuner 151, the error power amplifier 161, and the error cancellation IMDC coupler 184. The IMDC loop delay path 125 comprises a respective delay component 141, where the delay component 141, provided in the IMDC loop 118, generally closely matches the group delay of the error power amplifier path 126 of the IMDC loop 118 to the group delay of the IMDC loop delay path 125 of the IMDC loop 118, with minimal delay error in order to achieve optimal operational bandwidth.

The carrier input signal 101 is operatively coupled to the input to the FF amplifier 100 and hence the carrier input signal 101 is operatively coupled to both paths of the CC loop 117 (e.g., when the switch 102 is in the position shown in FIG. 1, in the online tuning state).

The main power amplifier path 123 receives the carrier input signal 101 and generates an amplified carrier signal 122 in an amplified main path of the FF amplifier 100.

Comparing the amplified carrier signal 122 with the carrier input signal 101, it is understood that amplification by the main power amplifier 121 has introduced distortions (e.g., errors) in the amplified carrier signal 122, which may, for example, be in the form of beat frequencies that are higher and/or lower than the carrier frequencies. Such beat frequencies, and the like, are understood to be removed from the carrier output signal 107 via the CC loop 117 and the IMDC loop 118 as described herein. Furthermore, while such beat frequencies may occur only when two carriers are present (e.g., as depicted), other types of distortions (e.g., errors) may be introduced in the amplified carrier signal 122 when only one carrier is present.

The amplified carrier signal 122 is operatively coupled to the carrier cancellation summing node 171 via the coupled path comprising the carrier cancellation couplers 181 and 182. The delay path 124 (e.g., the clean path) includes the delay component 131 that provides a time-delayed version of the carrier input signal 101 at the carrier cancellation summing node 171 (e.g., without the distortions of the amplified carrier signal 122). The resulting carrier cancellation error signal 172 is the output signal of CC loop 117.

In particular, during the tuning operation of the CC loop 117 performed by the processor 109, the phase and gain of the signal coupled from the amplified carrier signal 122 to the carrier cancellation summing node 171 is generally adjusted using the main path gain/phase tuner 111. This tuning is performed such that the resulting signal coupled from the main power amplifier path 123 to the carrier cancellation summing node 171 is at a substantially equal magnitude, and substantially 180 degrees apart from the time-delayed RF signal from the delay path 124 (e.g., the clean path) through the delay component 131 also coupled to the carrier cancellation summing node 171. The feedback to processor 109, for determination during the tuning process, is generally supplied by the cancellation RF power detector 114, which is located on an error power amplifier path 126 located after the carrier cancellation summing node 171. The detected power of the cancellation RF power detector 114 is substantially minimized when the CC loop 117 is optimally tuned.

Hence, the carrier cancellation summing node 171 cancels or reduces the carrier input signal 101 from the amplified carrier signal 122 and provides the carrier cancellation error signal 172 including the distortion components created by the main power amplifier 121, but with a reduced carrier signal component on the error power amplifier path 126.

For example, as depicted the resulting carrier cancellation error signal 172 is understood to include the error frequencies (e.g., distortions), depicted in solid lines, but not the carrier frequencies, depicted in broken lines to indicate their removal; this convention will be used throughout the present specification.

The amplified carrier signal 122 is input to the IMDC loop 118. Similarly, the carrier cancellation error signal 172 is input to the error path gain/phase tuner 151 and the error power amplifier 161.

The error power amplifier 161 amplifies the carrier cancellation error signal 172 generated by the carrier cancellation summing node 171, to generate an amplified carrier cancellation error signal 183 coupled to the error cancellation IMDC coupler 184. The error cancellation IMDC coupler 184 couples the amplified carrier cancellation error signal 183, out of phase by substantially 180 degrees with the amplified carrier signal 122, to cancel or reduce the distortions at the carrier output signal 107. The phase and gain of the amplified carrier cancellation error signal 183 are understood to be adjusted using the error path gain/phase tuner 151 the amplified carrier cancellation error signal 183 being out of phase by substantially 180 degrees. The delay component 141 in the IMDC loop delay path 125 is provided to generally match the delay caused by the error power amplifier 161 and other components in the error power amplifier path.

While not depicted, tuning of the IMDC loop 118 may occur in another offline tuning state using the PTG 112 and the PTR 113, both of which are controlled by the processor 109. A pilot tone generated by the PTG 112, may be turned on and off, as required, by the processor 109, and/or the pilot tone may be operatively removed in any suitable manner, such as via the use of a switch (not depicted), at the output of the PTG 112.

In general, in the absence of a carrier signal (e.g., an offline tuning state where the switch 102 may be at the position shown in FIG. 3, or any other suitable position), the PTG 112 may be controlled to output a pilot tone to introduce the pilot tone into the main power amplifier path 123 of the CC loop 117, and as such can be acted upon by the IMDC loop 118 in order to perform tuning of the IMDC loop 118 in an offline tuning state. The tone frequency of a pilot tone output by the PTG 112 may be controlled by the processor 109 to “steer” the tone frequency across various frequencies of a desired tuning bandwidth (e.g., across frequencies of carriers). Furthermore, while as depicted an output of the PTG 112 is between an output of the main path gain/phase tuner 111 and an input to the main power amplifier 121, an output of the PTG 112 may be after the output of the main power amplifier 121 (e.g., but before the main path carrier cancellation coupler 181), or before the input to the main path gain/phase tuner 111 (e.g., but after the input to the FF amplifier 100 so that a pilot tone is provided on the main path, but not on the clean path).

Furthermore, the pilot tone is understood to be at an amplitude that is generally much less than an amplitude of a carrier signal, for example 5%, 10%, 15% of an amplitude of a carrier signal, amongst other possibilities, though the amplitude of the pilot tone may be determined heuristically. In particular, the amplitude of the pilot tone may be selected to be a minimum amplitude needed to perform a tuning operation of the IMDC loop 118, which may be heuristically determined. Indeed, when a resulting output pilot tone is transmitted by the FF amplifier 100 (e.g., and not into the dump load 106), for example prior to optimal tuning, and/or a radio of which the FF amplifier 100 is a component, such an output pilot tone is understood to be at a transmit power that may be below a given power, such as a few milliwatts, and the like, within a short distance (e.g., 10 meters, 20 meters, 30 meters, amongst other possibilities) from the transmitter to satisfy regulatory requirements.

During the tuning operation of the IMDC loop 118, performed by the processor 109, the phase and gain of the signal coupled from a signal corresponding to the amplified carrier signal 122 (e.g., but including the frequency and/or frequencies of the pilot tone), is adjusted using the error path gain/phase tuner 151. This tuning is performed such that the resulting error signal coupled from the error power amplifier path 126 to the IMDC summing node 191 is at a substantially equal magnitude, and substantially 180 degrees apart from the IMDC products of the time-delayed RF signal from the IMDC loop delay path 125 through the delay component 141, also coupled to IMDC summing node 191. The resulting error signal is understood to include the pilot tone, and any distortions from the main power amplifier 121. The feedback to the processor 109, for determination during the tuning process is generally supplied by the PTR 113, which is located after the IMDC summing node 191. The PTR 113 may comprise a tuned receiver, that is locked to the tone/frequency injected by the PTG 112. The detected signal from the PTR 113 is substantially minimized (e.g., which may include complete cancellation) when the IMDC loop 118 is optimally tuned.

From this tuning process, startup IMDC loop tuning parameters may be determined, such as a gain and a phase shift used by the error path gain/phase tuner 151. Put another way, a gain and a phase shift that minimizes a detected signal from the PTR 113 may be used as startup loop tuning parameters the error path gain/phase tuner 151 when the carrier input signal 101 is received at the input to the FF amplifier 100. While additional tuning is understood to occur, as described herein with respect to FIG. 1, to generate the carrier output signal 107, the startup IMDC loop tuning parameters may be used as a starting point, in some examples.

However, an alternative offline IMDC loop tuning process is described with respect to FIG. 3.

Regardless of how the IMDC loop 118 is tuned, the IMDC summing node 191 generally cancels or reduces the distortion generated by the main power amplifier path 123 of the CC loop 117, primarily generated by the main power amplifier 121, resulting in the amplified carrier signal 122, which comprises an amplified version of the carrier input signal 101, with substantially reduced distortion components relative to amplified carrier signal 122. The resulting signal is the carrier output signal 107.

However, a tuning process of the IMDC loop 118 tuning may not be used to tune the CC loop 117 as a pilot tone from the PTG 112 is injected into the CC loop 117 at an input to the main power amplifier 121, and not at an input to the main power amplifier path 123 and the delay path 124 (e.g., the “clean path”).

However, such tuning may occur using the pilot tone generator 103, as is next described with respect to FIG. 2.

In these examples, it is understood that a predetermined relationship 199 may be heuristically determined between pilot tone CC loop tuning parameters 298 and carrier CC loop offset parameters 299 (e.g., labelled “CC Loop Offsets” in FIG. 2 for simplicity), described herein. The predetermined relationship 199 may comprise a lookup table, and the like, that relates pilot tone CC loop tuning parameters 298, a determined during pilot tone tuning of the CC loop 117, described herein with respect to FIG. 2, and the carrier CC loop offset parameters 299.

However, alternatively, or in addition, as will be explained below, a predetermined relationship 199 may be heuristically determined between pilot tone IMDC loop tuning parameters 398 and carrier IMDC loop offset parameters 399, described herein.

As such, the predetermined relationship 199 may be referred to as the predetermined relationship(s) 199 (e.g., in the plural), though depending on whether or not one, or the other, or both of CC loop tuning and IMDC loop tuning occurs, the predetermined relationship(s) 199 may include one, the other, or both of: a first relationship (e.g., in the form of a first lookup table) between pilot tone CC loop tuning parameters 298 and carrier CC loop offset parameters 299; and a second relationship (e.g., in the form of a second lookup table) between pilot tone IMDC loop tuning parameters 398 and carrier IMDC loop offset parameters 399.

Turning now to FIG. 2, tuning and/or pretuning of the CC loop 117 may occur in the depicted offline tuning state by the processor 109 controlling the switch 102 to an offline tuning position (that is used at least upon startup), in which a pilot tone 201 is received from the pilot tone generator 103. Tuning of at least the CC loop 117 may occur in a similar manner as described above with respect to the carrier input signal 101, such that a pilot tone output signal 207 is generated based on an amplified pilot tone signal 222, a pilot tone cancellation error signal 272, and an amplified pilot tone cancellation error signal 283. The signals 207, 222, 272, 283 are generally respectively similar to the signals 107, 122, 172, 183, but generated using the pilot tone 201. Furthermore, the pilot tone 201 may be similar to the pilot tone generated by the PTG 112. Furthermore, while the amplified pilot tone signal 222 shows mixing frequencies (e.g., on either side of the amplified frequency of the pilot tone), such mixing frequencies may or may not occur; regardless, distortions to the pilot tone 201 itself may be referred to as “present” distortions herein, to distinguish from distortions to the carrier input signal 101 (e.g., as the pilot tone 201 may be considered distortion to the carrier input signal 101, when combined).

In general, the predetermined relationship(s) 199 may relate gain and phase offsets of the main path gain/phase tuner 111, that optimizes cancellation of the pilot tone output signal 272 to gain and phase offsets of the main path gain/phase tuner 111 that optimizes the carrier output signal 272.

More specifically, the predetermined relationship(s) 199 is understood to be dependent on a temperature 280 of the main power amplifier 121, as well as a frequency 281 of the pilot tone 201 and a frequency 282 of a carrier input signal 101. While the frequency 281, 282 are generally known and/or predetermined by the processor 109, the temperature 280 of the main power amplifier 121 may be determined via the processor 109 communicating with a temperature sensor that is generally present at the main power amplifier 121, and which may include, but is not limited to, a thermistor, a temperature diode, a specialized integrated circuit (IC) temperature sensor, and the like.

Hence, as depicted, the processor 109 may input, to the predetermined relationship(s) 199, the pilot tone CC loop tuning parameters 298 (e.g., the gain and phase shift of the main path gain/phase tuner 111 where by the carrier summing node 171 power is substantially minimized), the temperature 280, and the frequencies 281, 282, to determine the carrier CC loop offset parameters 299. The carrier CC loop offset parameters 299 may comprise offsets with respect to the pilot tone CC loop tuning parameters 298.

The carrier CC loop offset parameters 299, such as a gain offset and a phase offset from gain and phase shifts of the pilot tone CC loop tuning parameters 298, may be used at the main path gain/phase tuner 111 when the carrier input signal 101 is keyed at a radio of which the FF amplifier 100 is a component.

The pilot tone 201 may be operatively removed from the input to the FF amplifier 100 when an indication of the carrier input signal 101 being keyed is received at the processor 109, though a pilot tone (e.g., from the PTG 112) may persist on the main power amplifier path 123 (but not the delay path 124).

With attention next directed to FIG. 3, it is further understood that the predetermined relationship(s) 199 may similarly relate gain and phase shift of the error path gain/phase tuner 151, that optimizes a pilot tone output signal 307 (e.g., pilot tone IMDC tuning parameters 398), to gain and phase shift of the error path gain/phase tuner 151 that may optimize a carrier output signal 307.

For example, in FIG. 3 shows an offline tuning state for tuning the IMDC loop 118, and the processor 109 controls the switch 102 to an offline tuning position where no signals are received at the input to the FF amplifier 100. Furthermore, the PTG 112 is controlled to inject a pilot tone 301 into the main power amplifier 121 and/or into any suitable location on the main power amplifier path 123.

When tuning of the IMDC loop 118 is successful, as is next described, a pilot tone output signal 307 is substantially minimized (e.g., as depicted, the pilot tone 301 and any present distortions are cancelled).

Tuning of at least the IMDC loop 118 may occur in a similar manner as described above with respect to the carrier input signal 101, such that the pilot tone output signal 307 is generated based on an amplified pilot tone signal 322, a pilot tone cancellation error signal 372, and an amplified pilot tone cancellation error signal 383. The signals 307, 322, 372, 383 are generally respectively similar to the signals 107, 122, 172, 183, but generated using the pilot tone 301. However, a main difference between such signals, is that the pilot tone cancellation error signal 372 includes both the pilot tone 301 and the distortions. In other words, the pilot tone cancellation error signal 372 is similar to the amplified pilot tone signal 322, with the amplified pilot tone cancellation error signal 383 being substantially 180 degrees out of phase with the amplified pilot tone signal 322.

Once the pilot tone output signal 307 is substantially minimized, as detected by the PTR 113, the predetermined relationship(s) 199 may be used to determine carrier IMDC loop offset parameters 398 of the IMDC loop 118.

For example, as depicted, the processor 109 may input, to the predetermined relationship(s) 199, the pilot tone IMDC loop tuning parameters 398 (e.g., the gain and phase shift of the IMDC path gain/phase tuner 151 when the pilot tone output signal 307 is substantially minimized), a temperature 380 of the error power amplifier 161, and the respective frequencies 381, 382 of the pilot tone 301 and a carrier (e.g., the carrier input signal 101) keyed at a radio of which the FF amplifier 100 is component, to determine carrier IMDC loop offset parameters 399 (e.g., labelled “IMDC Loop Offsets” in FIG. 3 for simplicity). The carrier IMDC loop offset parameters 399 may comprise offsets with respect to the pilot tone IMDC loop tuning parameters 398.

The carrier IMDC loop offset parameters 399, such as a gain offset and a phase offset from gain and phase shifts of the pilot tone IMDC loop tuning parameters 398, may be used at the error path gain/phase tuner 151 when the carrier input signal 101 is keyed at a radio of which the FF amplifier 100 is a component.

The pilot tone 301 may (or may not) be operatively removed from the input to the main power amplifier 121, and/or operatively removed from the main power path 123, when an indication of the carrier input signal 101 being keyed is received at the processor 109, similar to the pilot tone 201.

In these examples, it is understood that the predetermined relationship(s) 199 may be heuristically determined between the pilot tone IMDC loop tuning parameters 398 and the carrier IMDC loop offset parameters 399, such as offsets, described herein. The predetermined relationship(s) 199 may comprise a lookup table, and the like, that relates the carrier IMDC loop offset parameters 399 (e.g., for a carrier) to the pilot tone IMDC loop tuning parameters 398, described herein with respect to FIG. 3.

Indeed, in the examples of FIG. 2 and FIG. 3, the predetermined relationship(s) 199 are understood to comprise two lookup tables: a first lookup table for the pilot tone CC loop tuning parameters 298 and the carrier CC loop offset parameters 299, and a second lookup table for the pilot tone IMDC loop tuning parameters 398 and the carrier IMDC loop offset parameters 399. Indeed, for the first lookup table, temperature 280, and the frequencies 281, 282 may be components thereof (e.g., to be substantially matched, with temperature 280, and the frequencies 281, 282 input thereto); and, similarly, for the second lookup table, temperature 380, and the frequencies 381, 382 may be components thereof (e.g., to be substantially matched, with temperature 380, and the frequencies 381, 382 input thereto).

It is hence understood that the offline tuning of the IMDC loop 118 described with reference to FIG. 3, is similar to the online tuning of the IMDC loop 118 described with reference to FIG. 1, but with the carrier IMDC loop offset parameters 399 determined using the predetermined relationship(s) 199.

Furthermore, when the FF amplifier 100 is initially turned on and enters a startup state, the FF amplifier 100 may be placed into the offline tuning state depicted in FIG. 2 and/or FIG. 3 to determine the pilot tone CC loop tuning parameters 298 and/or the pilot tone IMDC loop tuning parameters 398, and which may be determined periodically until a carrier input signal 101 is keyed. Indeed, the pilot tone CC loop tuning parameters 298 and/or the pilot tone IMDC loop tuning parameters 398 may change over time as a temperature of the main power amplifier 121 changes.

Furthermore, when the FF amplifier 100 enters a post-startup state, the FF amplifier 100 may again be placed into the offline tuning state depicted in FIG. 2 and/or FIG. 3 to determine the pilot tone CC loop tuning parameters 298 and/or the pilot tone IMDC loop tuning parameters 398, and which may again be determined periodically until a carrier input signal 101 is keyed and/or again keyed. Indeed, in the post-startup state the pilot tone CC loop tuning parameters 298 and/or the pilot tone IMDC loop tuning parameters 398 may change over time as a temperature of the main power amplifier 121 changes.

When a carrier input signal 101 is keyed, the FF amplifier 100 transitions to the online tuning state depicted in FIG. 1 using the carrier CC loop offset parameters 299 determined using the pilot tone CC loop tuning parameters 298 and/or using the carrier IMDC loop offset parameters 399 determined using the pilot tone IMDC loop tuning parameters 398.

After the carrier input signal 101 is dekeyed (e.g., the post-startup state), the FF amplifier 100 may return to the offline tuning state depicted in FIG. 2 and/or FIG. 3.

Alternatively, when the simulated carrier generator 104 is present, the FF amplifier 100 may transition to the offline tuning state depicted in FIG. 4 (e.g., in an alternative post-startup state).

With attention next directed to FIG. 4, tuning of the CC loop 117 and/or the IMDC loop 118 may occur in the depicted offline tuning state by the processor 109 controlling the switch 102 to an offline tuning position, in which a simulated carrier signal 401 is received from the simulated carrier generator 104. Tuning of at least the CC loop 117 and/or the IMDC loop 118 may occur in a similar manner as described above with respect to the carrier input signal 101, such that a simulated carrier output signal 407 is generated based on an amplified simulated carrier signal 422, a simulated carrier cancellation error signal 472, and an amplified simulated carrier cancellation error signal 483. The signals 407, 422, 472, 483 are generally respectively similar to the signals 107, 122, 172, 183, but generated using the simulated carrier signal 401. Indeed, the simulated carrier output signal 407 is understood to have distortions removed and/or substantially minimized, that are present in the amplified simulated carrier signal 422. Furthermore, when the IMDC loop 118 is tuned (e.g., in the presence of the simulated carrier signal 401 input to the FF amplifier 100), the pilot tone generator 112 may be used in such tuning, similar to as described above with respect to FIG. 1.

In these examples, the switch 105 is optionally further set to a dump load position such that the simulated carrier output signal 407 is not substantially radiated over the air, but absorbed into the dump load 106.

A frequency and/or amplitude of the simulated carrier signal 401 may be respectively similar to frequency and/or amplitude of a carrier input signal 101. Hence, any CC loop tuning parameters (or IMDC loop tuning parameters) determined in the offline mode of FIG. 4, may be used when the FF amplifier 100 transitions to the online mode of FIG. 1. The tone frequency of the simulated carrier signal 401 may be controlled by the processor 109 to “steer” the tone frequency across various frequencies of a desired tuning bandwidth.

One skilled in the art will appreciate that the simulated carrier output signal 401 may comprise a single frequency carrier, or instead could comprise multiple carriers generation of two or more carriers as depicted in FIG. 4, for example.

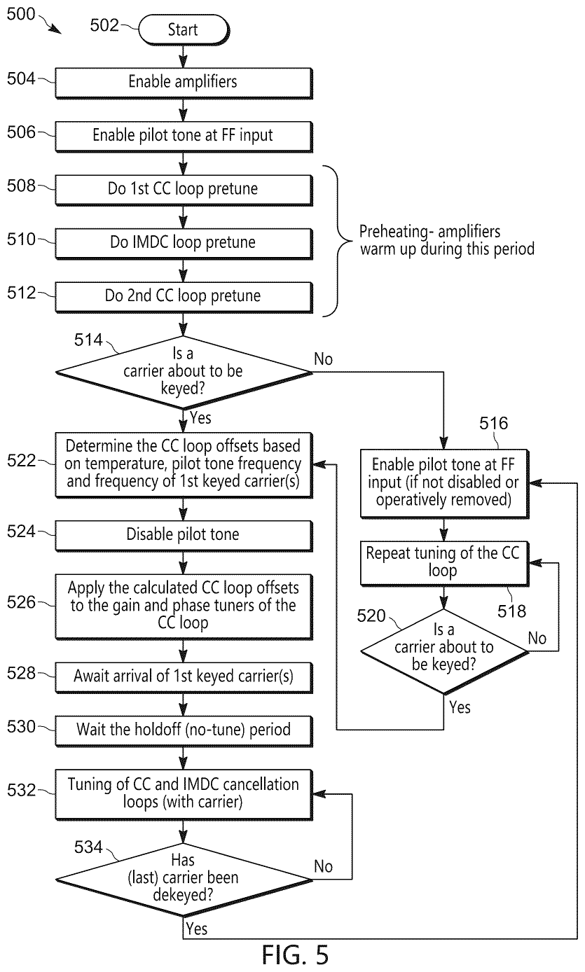

Attention is next directed to FIG. 5, which depicts a process 500 and/or set of operations for transitioning from offline to online tuning states in the feed-forward amplifier 100, which may be implemented by the processor 109 implementing programming instructions (e.g., stored at a memory location of the radio, and/or radio transmitter, of which the FF amplifier 100 is a component). The set of operations for implementing the process 500 may be stored at a memory and/or computer readable storage medium of the radio of which the feed-forward amplifier 100 is a component, and such memory and/or computer readable storage medium is understood to be represented by the component 109.

It is further understood that FIG. 5 will be initially described with reference to FIG. 1 and FIG. 2, assuming that offline tuning of the CC loop 117 occurs using the pilot tone 201 in the offline tuning state of FIG. 2, and that online tuning of the CC loop tuning occurs using the carrier input signal 101 in the online tuning state of FIG. 1.

At a block 502, the process 500 starts; for example, the FF amplifier 100 may be turned on when the radio, of which the FF amplifier 100 is a component, is turned on.

At a block 504, which may represent a startup state of the FF amplifier 100, the amplifiers 121, 161 are enabled, and/or turned on.

At a block 506, the pilot tone 201 is enabled at the input to the FF amplifier 100, and at a block 508, a first (and, in some examples, optional) tuning (e.g., a pretuning) of the CC loop 117 may occur as described with reference to FIG. 2.

At a block 510, a tuning (e.g., a pretuning) of the IMDC loop 118 may occur as described with reference to FIG. 3 (with or without determination of the pilot tone IMDC loop tuning parameters 398). The tuning of the block 510 may be optional. At the block 510, the pilot tone 201 may be operatively removed from the input of the feed-forward amplifier 100, and the pilot tone 301 enabled at the input to the main power amplifier 121 (and/or at any suitable location on the main power amplifier path 123). Such a process may occur via the switch 102, and the like.

At a block 512, a second tuning (e.g., a second pretuning) of the CC loop 117 may occur as described with reference to FIG. 2. At the block 512, if the pilot tone 201 was operatively removed from the input of the feed-forward amplifier 100, and the pilot tone 301 enabled, at the block 512, the pilot tone 301 may be operatively removed from the input to the main power amplifier 121, and/or main power amplifier path 123, and the pilot tone 201 operatively coupled back to the input of the feed-forward amplifier 100. Such a process may occur via the switch 102, and the like.

At the block 512, the pilot tone CC loop tuning parameters 298 may be determined and the carrier CC loop offset parameters 299 may be determined from the predetermined relationship(s) 199, or the carrier CC loop offset parameters 299 may be later determined once the carrier input signal 101 is keyed, as described below with respect to the block 516, as the temperature 280 of the main power amplifier 121 may continue to change between the block 512 and/or the carrier input signal 101 being keyed.

Hence, a preheating process may occur via the blocks 508, 510, 512 which results in the heating of the amplifiers 121, 161 in preparation for receipt of a carrier signal. Indeed, the preheating process generally allows the amplifiers 121, 161 to heat up so that when the carrier input signal 101 arrives, the amplifiers 121, 161 may be closer to a carrier operating temperature than if the preheating process were not implemented.

One skilled in the art will appreciate that such preheating may be achieved through any suitable process, including but not limited to biasing of amplifiers 121, 161 at or above nominal bias conditions, increased duration of tuning operations, repeated tuning iterations, or the like. Furthermore, the preheating may occur at one or more locations of the FF amplifier 100 (e.g., at one or both of the amplifiers 121, 161) throughout a given sequence of events (e.g., controlling one or both of the amplifiers 121, 161 to different biasing conditions), or at any suitable locations of the FF amplifier 100, in order to achieve the same preheating effect.

Put another way, the preheating process may allow temperature of the amplifiers 121, 161 to stabilize and/or at least partially stabilize, and/or to approach a carrier operating temperature such that later tuning of the CC loop, in the presence of the carrier input signal 101, may occur faster and/or more efficiently, and/or without exceeding certain transmission powers of the carrier output signal 107 (e.g., that may be set by a jurisdiction as being a maximum transmission power for radios).

At a block 514, the processor 109 determines whether a carrier is about to be keyed. For example, a push-to-talk button, and the like, may be depressed at the radio, and/or radio transmitter, of which the FF amplifier 100 is a component, which indicates to the processor 109 that the carrier input signal 101 is going to be received (e.g., about to be keyed) at the FF amplifier 100. For example, in general, such a radio and/or the processor 109 generally operates according to time slots of given time periods (e.g., such as about 15 ms, about 20 ms, about 25 ms, amongst other possibilities), and when the carrier is about to be keyed, it is understood that one or more of the time slots may pass before the carrier input signal 101 is received at the FF amplifier 100.

However, prior to discussing the process 500 with respect to a carrier about to be keyed, when a carrier is not about to be keyed (e.g., a “NO” decision at the block 514), at the blocks 516, 518, respectively, enabling of the pilot tone 201 may again occur (e.g., assuming that the pilot tone 201 was not previously removed from the input to the FF amplifier 100 and/or assuming that the pilot tone 201 was not previously disabled), and the tuning (e.g., petuning) of the CC loop 117 may again occur.

At the block 520, the processor 109 again determines whether the carrier is about to be keyed and, if not (e.g., a “NO” decision at the block 520), the blocks 516, 518, 520 are repeated.

Hence, tuning of the CC loop 117 using the pilot tone 201 may occur (e.g., repeatedly) until the processor 109 determines that the carrier is about to be keyed at the block 514 or the block 520 (e.g., a “YES” decision at the block 514 or the block 520). In each tuning of the CC loop 117, at least the pilot tone CC loop tuning parameters 298 may be determined.

When the carrier is about to be keyed (e.g., a “YES” decision at the block 514 or the block 520), at a block 522, the carrier CC loop offset parameters 299 are determined from the pilot tone CC loop tuning parameters 298 (e.g., using the predetermined relationship(s) 199), and as depicted, in FIG. 5, the carrier CC loop offset parameters 299 may comprise CC loop offsets for the gain shifter and the phase shifter of the main path gain/phase tuner 111. For example, such offsets may comprise shifts in settings applied to the previously determined pilot tone CC loop tuning parameters 298 to which the main path gain/phase tuner 111 have been set. In particular, the carrier CC loop offset parameters 299 are determined at the block 522 using the current temperature 280 of the main power amplifier 121.

At the block 524, the pilot tone 201 is optionally disabled and/or operatively removed from the input of the FF amplifier 100 (e.g., via the switch 102 being switched from the position of FIG. 2 to the position of FIG. 1) and, at a block 526, the carrier CC loop offset parameters 299 (e.g., as determined at the block 512 or 518), are applied to the main path gain/phase tuner 111 (e.g., the gain and phase tuners thereof). However, the pilot tone 201 may remain enabled during the remainder of the process 500.

At the block 528, the carrier input signal 101 may arrive and/or be received at the input to the FF amplifier 100, with the main path gain/phase tuner 111 tuned according to the carrier CC loop offset parameters 299 applied at the block 526.

At the block 530, the processor 109 waits a holdoff period, (e.g., 1 or more seconds depending on amplifier characteristics). After the holdoff period, at the block 532, tuning of the CC loop 117 and the IMDC loop 118 occurs as in FIG. 1. Put another way, the FF amplifier 100 transitions from the offline tuning state of FIG. 2 to the online tuning state of FIG. 1.

Furthermore, by waiting the holdoff period, a temperature of the main power amplifier 121 further stabilized in the presence of the carrier input signal 101. The temperature stabilization which occurs during this holdoff period may be pre-compensated for by the offsets applied through the predetermined relationship(s) 199, for example.

However, one skilled in the art will appreciate that timing allowances between carrier keying and offset application may occur, and may generally occur at substantially the same time, though either could occur before the other. Put another way, the block 526 may occur before or after the carrier input signal 101 is received at the input to the FF amplifier 100. However, the holdoff period nonetheless occurs before tuning of the CC loop 117 and the IMDC loop 118 occurs as in FIG. 1.

Hence, it is understood that tuning of CC loop 117 occurs in stages that includes: offline tuning using the pilot tone 201 as described with reference to FIG. 2; determining, and application of, the carrier CC loop offset parameters 299 before the carrier input signal 101 arrives, and/or when the carrier is about to be keyed; and when the carrier input signal 101 arrives, waiting a hold off period, before the online tuning of FIG. 1.

At a block 534, the processor 109 determines whether the carrier has been dekeyed or whether a last carrier has been dekeyed (e.g., when more than carrier was keyed while the block 522 to the block 534 are being implemented).

If not (e.g., a “NO” decision at the block 534), the block 532 repeats. If so, (e.g., a “YES” decision at the block 534), the loop represented by the blocks 516 to 520 is implemented. The process 500 may generally continue until the FF amplifier 100 is turned off (e.g., the radio, and/or radio transmitter, of which the FF amplifier 100 is turned off).

It is further understood that a similar process may occur with respect to the offline state of FIG. 3. In other words, rather than using the pilot tone 201 to pretune the CC loop 117 (e.g., prior to a carrier being keyed), the pilot tone 301 may be used to pretune the IMDC loop 118, with the pilot tone IMDC loop tuning parameters 398 being used to determine the carrier IMDC loop offset parameters 399. Such an example may include a second tuning of the IMDC loop at the block 512, rather than a second tuning of the CC loop 117.

Alternatively, the processor 109 may perform pretuning using both offline states depicted in FIG. 2 and FIG. 3, for example, as represented, at least partially, by the block 510. In such examples, a second tuning (e.g., pretuning) of the IMDC loop 118 may occur before or after the second tuning (e.g., pretuning) of the CC loop 117 at the block 512, with the pilot tones 201, 301 enabled and disabled appropriately. In these examples, at the blocks 516, 518, the tuning (e.g., pretuning) of the IMDC loop 118 may be repeated with the pilot tones 201, 301 enabled and disabled appropriately.

Hence, offline tuning (e.g., pretuning) may occur using one, or both, of the offline states depicted in FIG. 2 and FIG. 3. Indeed, as used herein, the term “pretuning” and the like, is understood to refer to tuning the FF amplifier 100 (e.g., tuning one or more of the loops 117, 118) prior to a carrier (e.g., the carrier input signal 101) being keyed at the radio, and/or radio transmitter, of which the FF amplifier 100 is a component. Pretuning may occur during the preheating process.

It is furthermore understood that the offline tuning state of FIG. 4 may be implemented after at least after one implementation of online tuning using the online tuning state of FIG. 1, for example in place of the blocks 516, 518. In such examples, the processor 109 may alternate between the offline tuning state of FIG. 3 and the online tuning state of FIG. 1, and use of the simulated carrier signal 401 is understood to maintain the amplifiers 121, 161 at an operating temperature commensurate with the carrier input signal 101.

Hence, it is understood that the process 500 may be adapted for IMDC loop, with IMDC tuning occurring at the block 510, using the pilot tone 301, and at which the pilot tone IMDC loop tuning parameters 398 are determined. In such examples, when the carrier is about to be keyed (e.g., a “YES” decision at the block 514 or the block 520), at the block 522, the carrier IMDC loop offset parameters 399 are determined from the pilot tone IMDC loop tuning parameters 398 (e.g., using the predetermined relationship(s) 199 and from ), and the carrier IMDC loop offset parameters 399 may comprise IMDC loop offsets for the gain shifter and the phase shifter of the error path gain/phase tuner 151. For example, such offsets may comprise shifts in settings applied to the previously determined pilot tone IMDC loop tuning parameters 398 to which the error path gain/phase tuner 151 have been set. In particular, in these examples, the carrier IMDC loop offset parameters 399 are determined at the block 522 using the current temperature 380 of the error power amplifier 161.

In these examples, at the block 524, the pilot tone 301 may be optionally disabled and/or operatively removed and, at a block 526, the carrier IMDC loop offset parameters 399 (e.g., as determined at the block 512 or 518), are applied to the error path gain/phase tuner 151 (e.g., the gain and phase tuners thereof). However, the pilot tone 301 may remain enabled during the remainder of the process 500.

In these examples, at the block 528, the carrier input signal 101 may arrive and/or be received at the input to the FF amplifier 100, with the error path gain/phase tuner 151 tuned according to the carrier IMDC loop offset parameters 399 applied at the block 526.

At the block 530, the processor 109 waits a holdoff period, (e.g., 1 or more seconds depending on amplifier characteristics). After the holdoff period, at the block 532, tuning of the CC loop 117 and the IMDC loop 118 occurs as in FIG. 1. Put another way, the FF amplifier 100 transitions from the offline tuning state of FIG. 3 to the online tuning state of FIG. 1.

Hence, it is understood that tuning of IMDC loop 118 may occurs in stages that includes: offline tuning using the pilot tone 301 as described with reference to FIG. 3; determining, and application of, the carrier IMDC loop offset parameters 399 before the carrier input signal 101 arrives, and/or when the carrier is about to be keyed; and when the carrier input signal 101 arrives, waiting a hold off period, before the online tuning of FIG. 1.

Furthermore, it is understood that the process 500, whether applied to the CC loop 117 and/or the IMDC loop 118, may occur using one or more tones (e.g., the pilot tone 201 and/or the pilot tone 301, multiple pilot tones (e.g., a pilot tone 201, 301 may comprise more than one pilot tone at different frequencies), and/or a correlator signal).

As should be apparent from this detailed description above, the operations and functions of the electronic computing device are sufficiently complex as to require their implementation on a computer system, and cannot be performed, as a practical matter, in the human mind. Electronic computing devices such as set forth herein are understood as requiring and providing speed and accuracy and complexity management that are not obtainable by human mental steps, in addition to the inherently digital nature of such operations (e.g., a human mind cannot tune FF amplifier loops, among other features and functions set forth herein).

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

Also, it should be understood that the illustrated components, unless explicitly described to the contrary, may be combined or divided into separate software, firmware, and/or hardware. For example, instead of being located within and performed by a single electronic processor, logic and processing described herein may be distributed among multiple electronic processors. Similarly, one or more memory modules and communication channels or networks may be used even if embodiments described or illustrated herein have a single such device or element. Also, regardless of how they are combined or divided, hardware and software components may be located on the same computing device or may be distributed among multiple different devices. Accordingly, in this description and in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

It will be appreciated that some embodiments may be comprised of one or more generic or specialized processors (or “processing devices”) such as microprocessors, digital signal processors, customized processors and field programmable gate arrays (FPGAs) and unique stored program instructions and/or program code (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions and/or program code, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Any suitable computer-usable or computer readable medium may be utilized. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. In the context of this document, a computer-usable or computer-readable medium may be any medium that can contain, store, communicate, propagate, or transport the program for use by or in connection with the instruction execution system, apparatus, or device.

Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation. For example, computer program code for carrying out operations of various example embodiments may be written in an object oriented programming language such as Java, Smalltalk, C++, Python, or the like. However, the computer program code for carrying out operations of various example embodiments may also be written in conventional procedural programming languages, such as the “C” programming language or similar programming languages. The program code may execute entirely on a computer, partly on the computer, as a stand-alone software package, partly on the computer and partly on a remote computer or server or entirely on the remote computer or server. In the latter scenario, the remote computer or server may be connected to the computer through a local area network (LAN) or a wide area network (WAN), or the connection may be made to an external computer (for example, through the Internet using an Internet Service Provider).

The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “one of”, without a more limiting modifier such as “only one of”, and when applied herein to two or more subsequently defined options such as “one of A and B” should be construed to mean an existence of any one of the options in the list alone (e.g., A alone or B alone) or any combination of two or more of the options in the list (e.g., A and B together).

A device or structure that is “configured” in a certain way is configured in at least that way, but may also be configured in ways that are not listed.

The terms “coupled”, “coupling” or “connected” as used herein can have several different meanings depending on the context in which these terms are used. For example, the terms coupled, coupling, or connected can have a mechanical or electrical connotation. For example, as used herein, the terms coupled, coupling, or connected can indicate that two elements or devices are directly connected to one another or connected to one another through intermediate elements or devices via an electrical element, electrical signal or a mechanical element depending on the particular context.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. A method implemented at a radio transmitter comprising a feed-forward amplifier comprising a carrier cancellation (CC) loop and an intermodulation cancellation (IMDC) loop, the method comprising:
in an absence of carriers, implementing a preheating process comprising:
enabling a main power amplifier of the CC loop;
enabling one or more tones at a predetermined frequency and a predetermined power operatively coupled to an input of the feed-forward amplifier; and
tuning the CC loop using the one or more tones and determining tone CC loop tuning parameters; and
when a carrier is about to be keyed at the radio transmitter:
determining carrier CC loop offset parameters from the tone CC loop tuning parameters; and
applying the carrier CC loop offset parameters to the CC loop.

2. The method of claim 1, wherein the one or more tones comprises one or more of:
a pilot tone;
multiple tones;
a correlator signal.

3. The method of claim 1, further comprising, when the carrier is about to be keyed at the radio transmitter:
operatively removing the one or more tones from the input of the feed-forward amplifier.

4. The method of claim 1, wherein the CC loop offset parameters comprise one or more of respective gain offset settings for a gain tuner of the CC loop and respective phase offset settings for a phase tuner of the CC loop.

5. The method of claim 1, wherein the CC loop offset parameters are determined from one or more of: a temperature of the main power amplifier, a frequency of the one or more tones, and a respective frequency of the carrier.

6. The method of claim 1, wherein the preheating process further comprises, prior to tuning the CC loop using the one or more tones and determining the tone CC loop tuning parameters:
initially tuning the CC loop; and
tuning the IMDC loop.

7. The method of claim 1, further comprising, when the carrier is keyed at the radio transmitter, and after applying the CC loop offset parameters to the CC loop:
waiting a holdoff period; and
performing tuning of the CC loop in a presence of the carrier.

8. The method of claim 1, further comprising, after the carrier is dekeyed at the radio transmitter:
when disabled, again enabling the one or more tones at the input to the feed-forward amplifier; and
again tuning the CC loop using the one or more tones and again determining the tone CC loop tuning parameters for use with a next carrier.

9. The method of claim 1, further comprising, after tuning the CC loop using the one or more tones and determining the tone CC loop tuning parameters, and when the carrier is not about to be keyed at the radio transmitter:
when disabled, again enabling the one or more tones at the input; and
again tuning the CC loop using the one or more tones and again determining the tone CC loop tuning parameters for use with a next carrier.

10. The method of claim 1, further comprising, after the carrier is dekeyed at the radio transmitter:
enabling a simulated carrier at the input having a respective predetermined frequency and a respective power;
again tuning the CC loop using the simulated carrier and determining simulated carrier CC loop offset parameters for use with a next carrier; and
when the next carrier is about to be keyed at the radio transmitter:
applying the simulated carrier CC loop offset parameters to the CC loop in preparation for receiving the next carrier.

11. A radio transmitter comprising:
a feed-forward amplifier comprising a carrier cancellation (CC) loop and an intermodulation cancellation (IMDC) loop;
a processor; and
a computer-readable storage medium having stored thereon program instructions that, when executed by the processor, causes the processor to perform a set of operations comprising:
in an absence of carriers, implementing a preheating process comprising:
enabling a main power amplifier of the CC loop;
enabling one or more tones at a predetermined frequency and a predetermined power operatively coupled to an input of the feed-forward amplifier; and
tuning the CC loop using the one or more tones and determining tone CC loop tuning parameters; and
when a carrier is about to be keyed at the radio transmitter:
determining carrier CC loop offset parameters from the tone CC loop tuning parameters; and
applying the carrier CC loop offset parameters to the CC loop.

12. A method implemented at a radio transmitter comprising a feed-forward amplifier comprising a carrier cancellation (CC) loop and an intermodulation cancellation (IMDC) loop, the method comprising:
in an absence of carriers, implementing a preheating process comprising:
enabling an error power amplifier of the IMDC loop;
enabling a one or more tones at a predetermined frequency and a predetermined power within the main power amplifier path; and
tuning the IMDC loop using the one or more tones and determining tone IMDC loop tuning parameters; and
when a carrier is about to be keyed at the radio transmitter:
determining carrier IMDC loop offset parameters from the tone IMDC loop tuning parameters; and
applying the carrier IMDC loop offset parameters to the IMDC loop.

13. The method of claim 12, wherein the one or more tones comprises one or more of:
a pilot tone;
multiple tones;
a correlator signal.

14. The method of claim 12, wherein the IMDC loop offset parameters are determined from one or more of; a temperature of the error power amplifier, a frequency of the one or more tones, and a respective frequency of the carrier 15. The method of claim 12, further comprising, when the carrier is about to be keyed at the radio transmitter:
operatively removing the one or more tones from the main power amplifier path.

16. The method of claim 12, wherein the carrier IMDC loop offset parameters comprise one or more of respective gain offset settings for a gain tuner of the IMDC loop and respective phase offset settings for a phase tuner of the IMDC loop.

17. The method of claim 12, wherein the preheating process further comprises, prior to tuning the IMDC loop using the one or more tones and determining the tone IMDC loop tuning parameters:
initially tuning the IMDC loop; and
initially tuning the CC loop.

18. The method of claim 12, further comprising, when the carrier is keyed at the radio transmitter, and after applying the IMDC loop tuning parameters to the IMDC loop:
waiting a holdoff period; and
performing tuning of the IMDC loop in a presence of the carrier.

19. The method of claim 12, further comprising, after the carrier is dekeyed at the radio transmitter:
when disabled, again enabling the one or more tones at the main power amplifier path; and
when disabled, again tuning the IMDC loop using the one or more tones and again determining the tone IMDC loop tuning parameters for use with a next carrier.

20. The method of claim 12, further comprising, after tuning the IMDC loop using the one or more tones and determining the tone IMDC loop tuning parameters, and when the carrier is not about to be keyed at the radio transmitter:
when disabled, again enabling the one or more tones at the main power amplifier path; and
again tuning the IMDC loop using the one or more tones and again determining the tone IMDC loop tuning parameters for use with a next carrier.
